(19) United States
(12) Patent Application Publication
(10) Pub. No.: US 2025/0253621 A1
(43) Pub. Date: Aug. 7, 2025

(54) SEMICONDUCTOR OPTICAL DEVICE AND METHOD OF MANUFACTURING SEMICONDUCTOR OPTICAL DEVICE

(71) Applicant: SUMITOMO ELECTRIC INDUSTRIES, LTD., Osaka (JP)

(72) Inventors: Takuo HIRATANI, Osaka-shi (JP); Takehiko KIKUCHI, Osaka-shi (JP); Naoko INOUE, Osaka-shi (JP)

(73) Assignee: SUMITOMO ELECTRIC INDUSTRIES, LTD., Osaka (JP)

(21) Appl. No.: 19/021,502

(22) Filed: Jan. 15, 2025

(30) Foreign Application Priority Data
Feb. 6, 2024 (JP) 2024-016417

(51) Int. Cl. H01S 5/22; H01S 5/02; H01S 5/343

(52) U.S. Cl. CPC H01S 5/22; H01S 5/021; H01S 5/3434

(57) ABSTRACT

A semiconductor optical device includes a substrate having a silicon layer, and a semiconductor element formed of a III-V group compound semiconductor and bonded to the silicon layer. The silicon layer includes a first waveguide, a first recess, a terrace, and a first slab portion. The first recess is a recessed portion lower than a surface of the first waveguide, a surface of the terrace, and a surface of the first slab portion. The first recess and the terrace are disposed in this order on each of two sides of the first waveguide. The first waveguide is connected to one end of the first slab portion. The first slab portion is connected to the terrace. The semiconductor element includes a second slab portion, a projecting portion, and a mesa. The second slab portion is located on or above the first slab portion.

### CROSS REFERENCE TO RELATED APPLICATIONS

This application claims priority based on Japanese Patent Application No. 2024-016417 filed on Feb. 6, 2024, and the entire contents of the Japanese patent application are incorporated herein by reference.

### TECHNICAL FIELD

The present disclosure relates to a semiconductor optical device and a method of manufacturing a semiconductor optical device.

### BACKGROUND

A semiconductor element formed of a compound semiconductor and having an optical gain is bonded to a substrate such as a silicon on insulator (SOI) substrate (silicon photonics) in which a waveguide is formed, whereby a hybrid semiconductor optical device can be formed (for example, Non-patent literature 1: D. Huang, et al. “High-power sub-kHz linewidth lasers fully integrated on silicon” Optica Vol. 6, No. 6 745-752 (June 2019)). After the bonding, etching or the like is performed on the semiconductor element. Light is transferred between the waveguide of silicon and the semiconductor element.

### SUMMARY

A semiconductor optical device according to the present disclosure includes a substrate having a silicon layer, and a semiconductor element formed of a III-V group compound semiconductor and bonded to the silicon layer. The silicon layer includes a first waveguide, a first recess, a terrace, and a first slab portion. The first recess is a recessed portion lower than a surface of the first waveguide, a surface of the terrace, and a surface of the first slab portion. The first recess and the terrace are disposed in this order on each of two sides of the first waveguide. The first waveguide is connected to one end of the first slab portion. The first slab portion is connected to the terrace. The semiconductor element includes a second slab portion, a projecting portion, and a mesa. The second slab portion is located on or above the first slab portion. The projecting portion projects from the second slab portion to be located on or above the first waveguide. The mesa is located on or above the second slab portion and the projecting portion.

### BRIEF DESCRIPTION OF THE DRAWINGS

FIG. 1 is a plan view illustrating a semiconductor optical device according to an embodiment.

FIG. 2A is a plan view enlarged around the transition structure.

FIG. 2B is a plan view illustrating a substrate.

FIG. 3A is a cross-sectional view illustrating a semiconductor optical device.

FIG. 3B is a cross-sectional view illustrating a semiconductor optical device.

FIG. 3C is a cross-sectional view illustrating a semiconductor optical device.

FIG. 4A is a cross-sectional view illustrating a semiconductor optical device.

FIG. 4B is a cross-sectional view illustrating a semiconductor optical device.

FIG. 4C is a cross-sectional view illustrating a semiconductor optical device.

FIG. 5A is a diagram illustrating the calculation result of transmittance.

FIG. 5B is a diagram illustrating the calculation result of transmittance.

FIG. 6 is a plan view illustrating a method of manufacturing a semiconductor optical device.

FIG. 7A is a cross-sectional view illustrating a method of manufacturing a semiconductor optical device.

FIG. 7B is a cross-sectional view illustrating a method of manufacturing of a semiconductor optical device.

FIG. 7C is a cross-sectional view illustrating a method of manufacturing of a semiconductor optical device.

FIG. 8A is a cross-sectional view illustrating a method of manufacturing of a semiconductor optical device.

FIG. 8B is a cross-sectional view illustrating a method of manufacturing of a semiconductor optical device.

FIG. 8C is a cross-sectional view illustrating a method of manufacturing of a semiconductor optical device.

FIG. 9 is a plan view illustrating a method of manufacturing of a semiconductor optical device.

FIG. 10A is a cross-sectional view illustrating a method of manufacturing of a semiconductor optical device.

FIG. 10B is a cross-sectional view illustrating a method of manufacturing of a semiconductor optical device.

FIG. 10C is a cross-sectional view illustrating a method of manufacturing of a semiconductor optical device.

FIG. 11A is a cross-sectional view illustrating a method of manufacturing of a semiconductor optical device.

FIG. 11B is a cross-sectional view illustrating a method of manufacturing of a semiconductor optical device.

FIG. 11C is a cross-sectional view illustrating a method of manufacturing of a semiconductor optical device.

FIG. 12 is a plan view illustrating a method of manufacturing of a semiconductor optical device.

FIG. 13A is a cross-sectional view illustrating a method of manufacturing of a semiconductor optical device.

FIG. 13B is a cross-sectional view illustrating a method of manufacturing of a semiconductor optical device.

FIG. 13C is a cross-sectional view illustrating a method of manufacturing of a semiconductor optical device.

FIG. 14A is a cross-sectional view illustrating a method of manufacturing of a semiconductor optical device.

FIG. 14B is a cross-sectional view illustrating a method of manufacturing of a semiconductor optical device.

FIG. 14C is a cross-sectional view illustrating a method of manufacturing of a semiconductor optical device.

FIG. 15 is a plan view illustrating a method of manufacturing of a semiconductor optical device.

FIG. 16A is a cross-sectional view illustrating a method of manufacturing of a semiconductor optical device.

FIG. 16B is a cross-sectional view illustrating a method of manufacturing of a semiconductor optical device.

FIG. 16C is a cross-sectional view illustrating a method of manufacturing of a semiconductor optical device.

FIG. 17A is a cross-sectional view illustrating a method of manufacturing of a semiconductor optical device.

FIG. 17B is a cross-sectional view illustrating a method of manufacturing of a semiconductor optical device.

FIG. 17C is a cross-sectional view illustrating a method of manufacturing of a semiconductor optical device.

FIG. 18 is a plan view illustrating a semiconductor optical device according to a comparative example.

FIG. 19A is a cross-sectional view illustrating a semiconductor optical device.

FIG. 19B is a cross-sectional view illustrating a semiconductor optical device.

FIG. 19C is a cross-sectional view illustrating a semiconductor optical device.

FIG. 20A is a plan view illustrating a semiconductor optical device according to a modification.

FIG. 20B is a plan view illustrating a substrate.

### DETAILED DESCRIPTION

A groove (trench) is provided in the substrate. Etchants may enter the trench, and the semiconductor element may be etched from the bonding interface. In order to reduce damage to the semiconductor element, it is required to reduce unintended etching. In order to reduce the loss of light, it is required to increase the coupling efficiency between the waveguide and the semiconductor element. Thus, an object is to provide a semiconductor optical device and a method of manufacturing the semiconductor optical device, which can reduce unintended etching and reduce the loss of light.

### Description of Embodiments of Present Disclosure

First, the contents of embodiment of the present disclosure will be listed and explained.

(1) A semiconductor optical device according to one aspect of the present disclosure includes a substrate having a silicon layer, and a semiconductor element formed of a III-V group compound semiconductor and bonded to the silicon layer. The silicon layer includes a first waveguide, a first recess, a terrace, and a first slab portion. The first recess is a recessed portion lower than a surface of the first waveguide, a surface of the terrace, and a surface of the first slab portion. The first recess and the terrace are disposed in this order on each of two sides of the first waveguide. The first waveguide is connected to one end of the first slab portion. The first slab portion is connected to the terrace. The semiconductor element includes a second slab portion, a projecting portion, and a mesa. The second slab portion is located on or above the first slab portion. The projecting portion projects from the second slab portion to be located on or above the first waveguide. The mesa is located on or above the second slab portion and the projecting portion. The first slab portion is connected to the terrace, and the first recess terminates in the vicinity of an end of the first slab portion. Since the first recess terminates before the semiconductor element, unintended etching of the semiconductor element can be reduced. Since light is confined around the mesa of the semiconductor element, it is possible to reduce the loss of light.

(2) In the above (1), the silicon layer may include a second waveguide and a second recess. The second waveguide may be connected to an end of the first slab portion, and the end is opposite to the first waveguide. The second recess and the terrace may be disposed in this order on each of two sides of the second waveguide. The first slab portion may be located between the first recess and the second recess. The second slab portion may be located on or above the first slab portion, the second waveguide, the second recess, and the terrace that is disposed on each of two sides of the second waveguide. The mesa may extend from a position at which the mesa overlaps the first waveguide to a position at which the mesa overlaps the second waveguide. Since the second recess is closed by the first slab portion and the second slab portion, the etchant is kept from entering into the second recess.

(3) In the above (1) or (2), the semiconductor element may have a first semiconductor layer, an active layer, and a second semiconductor layer. The first semiconductor layer, the active layer, and the second semiconductor layer may be stacked so as to be located closer to the substrate in this order. The projecting portion may include the first semiconductor layer. The second slab portion may include the first semiconductor layer and the active layer. A portion of the mesa located on or above the projecting portion may include the active layer and the second semiconductor layer. A portion of the mesa located on or above the second slab portion may include the second semiconductor layer. Since light is confined around the mesa of the semiconductor element, it is possible to reduce the loss of light.

(4) In the above (3), the first semiconductor layer and the second semiconductor layer may each contain indium phosphide. The active layer may contain gallium indium arsenide phosphide. The semiconductor element is processed by wet-etching. The etchant is kept from entering into the second recess. Unintended etching of the semiconductor element can be reduced.

(5) In the above (3) or (4), the first semiconductor layer may be an n-type semiconductor layer. The second semiconductor layer may be a p-type semiconductor layer. A p-i-n structure is formed, and current can be injected into the active layer.

(6) In any one of the above (1) to (5), the projecting portion may be located on an inner side of the first waveguide. The mesa may be located on an inner side of the projecting portion. Etching of the semiconductor element from the bonding interface can be reduced. The projecting portion and the mesa are easy to manufacture.

(7) In any one of the above (1) to (6), the first waveguide may include a first tapered portion. The projecting portion may include a second tapered portion. The mesa may include a third tapered portion. A width of the first tapered portion, a width of the second tapered portion, and a width of the third tapered portion may each increase as a distance from the first slab portion decreases and may each decrease as the distance from the first slab portion increases. Since the coupling efficiency between the substrate and the semiconductor element is increased, it is possible to reduce the loss of light.

(8) In the above (7), the second tapered portion may be bonded to the first tapered portion. The third tapered portion may be located on or above the second tapered portion. Since the coupling efficiency between the substrate and the semiconductor element is increased, it is possible to reduce the loss of light.

(9) In any one of the above (1) to (8), the semiconductor optical device may include an insulating film covering the silicon layer and the semiconductor element. The insulating film functions as a cladding layer. It is possible to reduce the loss of light.

(10) A method of manufacturing a semiconductor optical device includes: bonding a semiconductor element to a silicon layer of a substrate, the semiconductor element being formed of a III-V group compound semiconductor; and wet-etching the semiconductor element that has been bonded. The silicon layer includes a first waveguide, a first recess, a terrace, and a first slab portion. The first recess is a recessed portion lower than a surface of the first waveguide, a surface of the terrace, and a surface of the first slab portion. The first recess and the terrace are disposed in this order on each of two sides of the first waveguide. The first waveguide is connected to one end of the first slab portion. The first slab portion is connected to the terrace. The bonding the semiconductor element is bonding the semiconductor element to the first waveguide, the first slab portion, and the terrace that is disposed on each of the two sides of the first waveguide. In the wet-etching, a second slab portion, a projecting portion, and a mesa are formed at the semiconductor element. The second slab portion is located on or above the first slab portion. The projecting portion projects from the second slab portion to be located on or above the first waveguide. The mesa is located on or above the second slab portion and the projecting portion. Unintended etching of the semiconductor element can be reduced. Since light is confined around the mesa of the semiconductor element, it is possible to reduce the loss of light.

(11) In the above (10), the silicon layer may include a second waveguide and a second recess. The second waveguide may be connected to an end of the first slab portion, and the end is opposite to the first waveguide. The second recess and the terrace may be disposed in this order on each of two sides of the second waveguide. The first slab portion may be located between the first recess and the second recess. The bonding may be bonding the semiconductor element to the first waveguide, the first slab portion, the second waveguide, and the terrace that is disposed on each of the two sides of the first waveguide and on each of the two sides of the second waveguide. The mesa may extend from a position at which the mesa overlaps the first waveguide to a position at which the mesa overlaps the second waveguide. Since the second recess is closed by the first slab portion and the second slab portion, the etchant is kept from entering into the second recess.

### Details of Embodiments of Present Disclosure

Specific examples of a semiconductor optical device and a method of manufacturing of a semiconductor optical device according to embodiment of the present disclosure will be described below with reference to the drawings. It is noted that, the present disclosure is not limited to these examples, but is defined by the scope of the claims, and is intended to include all modifications within the meaning and scope equivalent to the scope of the claims.

### Embodiment

### Semiconductor Optical Device

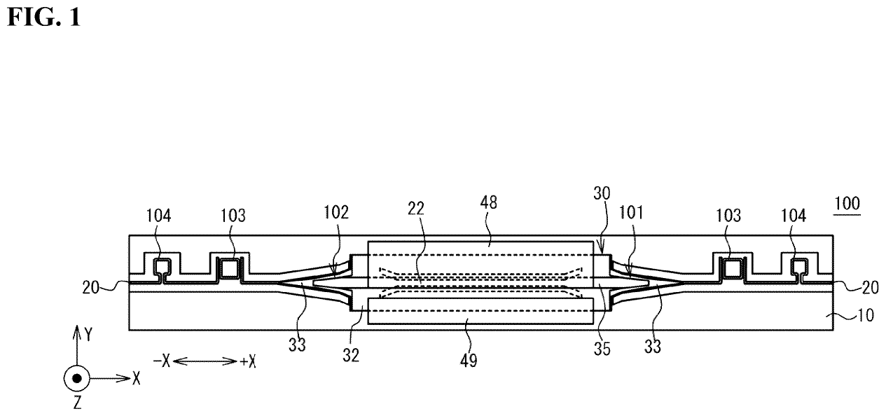

FIG. 1 is a plan view illustrating a semiconductor optical device 100 according to an embodiment. Semiconductor optical device 100 is a hybrid type wavelength tunable laser diode, and includes a substrate 10 and a semiconductor element 30. Semiconductor element 30 has an optical gain and is bonded to one surface of substrate 10. The Z-axis direction is a normal direction of a top surface of substrate 10. The X-axis direction is a direction parallel to a waveguide. One direction along the X-axis is defined as a +X direction. The direction opposite to the +X direction is defined as a −X direction. The Y-axis direction is orthogonal to the X-axis direction and the Z-axis direction.

Semiconductor optical device 100 includes a transition structure 101, a transition structure 102, two ring resonators 103, and two loop mirrors 104. In the X-axis direction, loop mirror 104, ring resonator 103, transition structure 102, semiconductor element 30, transition structure 101, ring resonator 103, and loop mirror 104 are arranged in this order. A laser resonator is formed by these components.

Ring resonator 103 and loop mirror 104 are provided on substrate 10. Transition structure 101 and transition structure 102 are portions that cause light to transfer between substrate 10 and semiconductor element 30, and are formed of substrate 10 and semiconductor element 30.

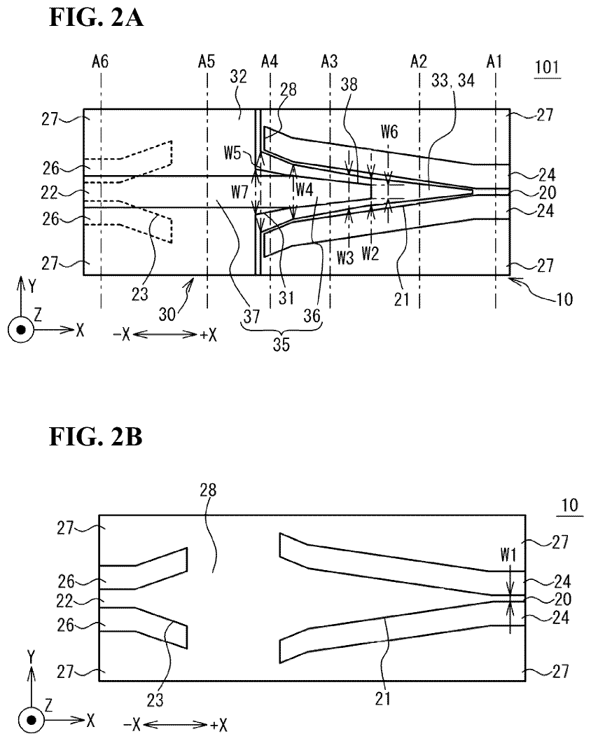

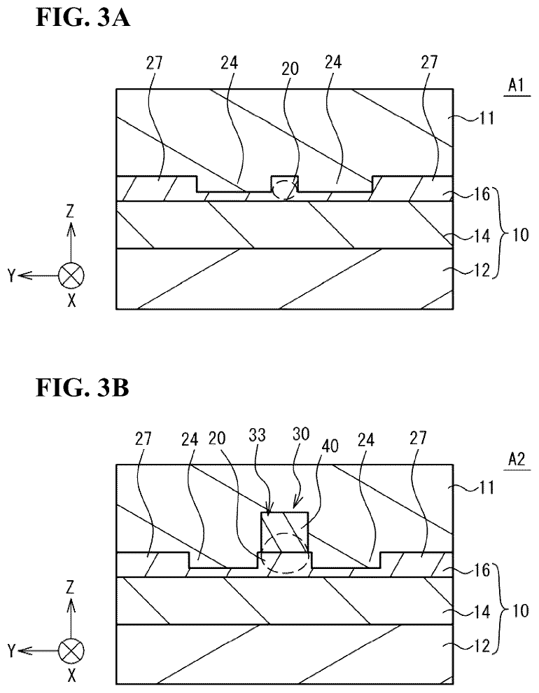

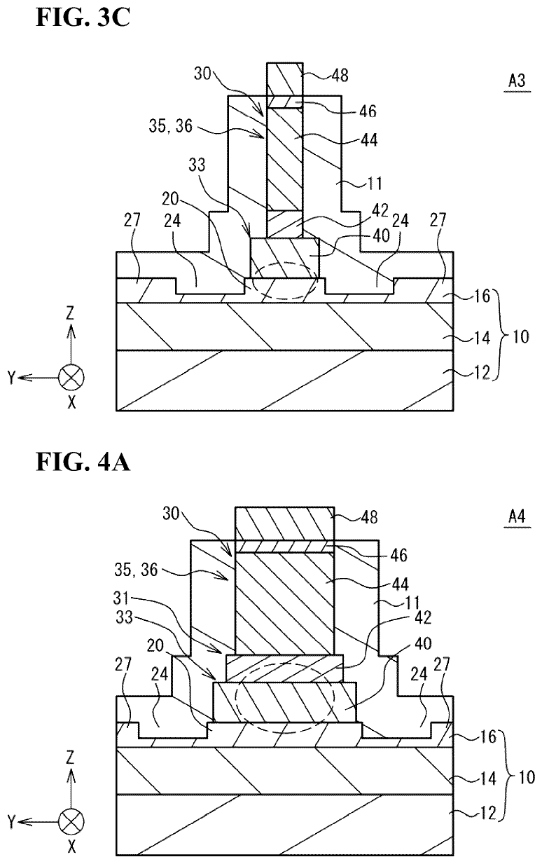

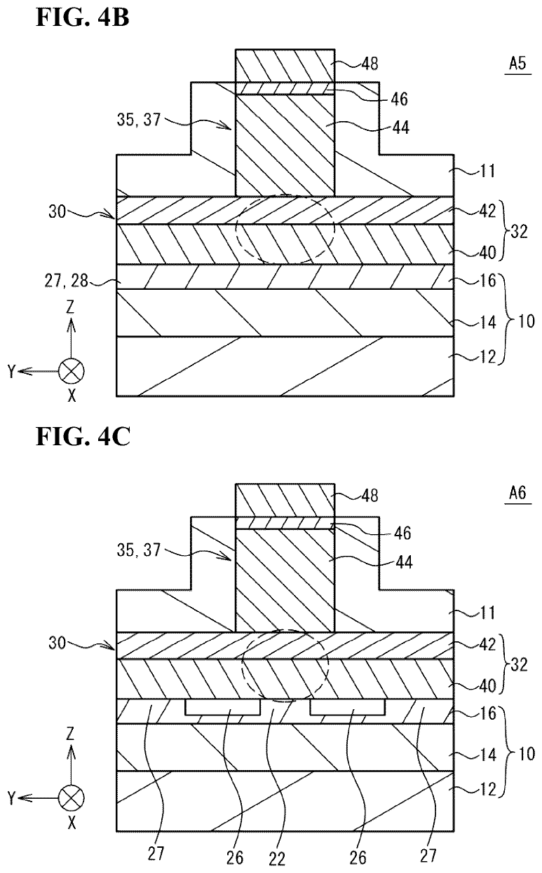

FIG. 2A is a plan view enlarged around transition structure 101. FIG. 2B is a plan view illustrating substrate 10, in which semiconductor element 30 is removed from FIG. 2A. FIG. 3A to FIG. 4C are cross-sectional views illustrating semiconductor optical device 100, in which cross-sections taken along a line A1, a line A2, a line A3, a line A4, a line A5, and a line A6 of FIG. 2A, are illustrated respectively. The light distribution is illustrated by dashed lines in FIG. 3A to FIG. 4C.

As illustrated in FIG. 3A to FIG. 4C, substrate 10 is a silicon on insulator (SOI) substrate, and includes a substrate 12, a BOX layer 14, and a silicon (Si) layer 16, which are stacked in order in the Z-axis direction. Substrate 12 is formed of, for example, Si. BOX layer 14 is formed of, for example, silicon oxide (SiO₂). The thickness of BOX layer 14 is, for example, 3 μm. The thickness of silicon layer 16 is, for example, 220 nm. The top surface of substrate 10 and a surface of semiconductor element 30 are covered with an insulating film 11. Insulating film 11 is formed of, for example, SiO₂ having a thickness of 1 μm. The refractive index of silicon layer 16 is 3.45. The refractive index of each of BOX layer 14 and insulating film 11 is 1.45, which is lower than that of silicon layer 16. A functional portion such as a waveguide is provided in silicon layer 16 of substrate 10.

As illustrated in FIG. 2A and FIG. 2B, substrate 10 includes a waveguide 20 (first waveguide), a waveguide 22 (second waveguide), a recess 24 (first recess), a recess 26 (second recess), a terrace 27, and a slab portion 28 (first slab portion).

Waveguide 20, slab portion 28, and waveguide 22 are arranged in this order from the +X side toward the −X side. Waveguide 20 is connected to one end (+X side end) of slab portion 28 in the X-axis direction. Waveguide 22 is connected to the other end (−X side end) of slab portion 28. Waveguide 20 and waveguide 22 are parallel to the X-axis direction.

Waveguide 20 has a tapered portion 21 (first tapered portion). Waveguide 22 has a tapered portion 23. A width of tapered portion 21 and a width of tapered portion 23 each increase as a distance from slab portion 28 decreases and each decrease as the distance from slab portion 28 increases. A width W1 at a tip of waveguide 20 illustrated in FIG. 2B is, for example, 420 nm. The dimensions of waveguide 22 may be the same as or different from the dimensions of waveguide 20. The dimensions of recess 26 may be the same as or different from the dimensions of recess 24.

In the Y-axis direction, recess 24 and terrace 27 are provided in this order on each of two sides of waveguide 20. That is, recess 24 is disposed adjacent to waveguide 20. Terrace 27 is placed on the opposite side of recess 24 from waveguide 20. Recess 26 and terrace 27 are provided in this order on each of two sides of waveguide 22. Recess 24 extends along waveguide 20 and has a taper shape corresponding to tapered portion 21 of waveguide 20. Recess 26 extends along waveguide 22 and has a taper shape corresponding to tapered portion 23 of waveguide 22.

Slab portion 28 is plate-shaped, is located between recess 24 and recess 26, and is connected to two terraces 27 on two sides of the waveguide. Recess 24 and recess 26 are blocked by slab portion 28.

As illustrated in FIG. 3A to FIG. 4A, waveguide 20 and terrace 27 are portions of silicon layer 16 which project from recess 24 in the Z-axis direction (upward). A surface of waveguide 20 is located at the same height as a surface of terrace 27. Recess 24 is a recessed portion lower than the surfaces of waveguide 20 and terrace 27. As illustrated in FIG. 4C, a surface of waveguide 22 is located at the same height as the surface of terrace 27. Recess 26 is a recessed portion lower than the surfaces of waveguide 22 and terrace 27. Silicon layer 16 serves as bottom surfaces of recess 24 and recess 26. The thickness of silicon layer 16 in the recess is, for example, 30 nm. Recess 24 and recess 26 may extend to the middle of silicon layer 16 in the Z-axis direction, or may extend to BOX layer 14 through silicon layer 16. Insulating film 11 is embedded in recess 24 and recess 26.

As illustrated in FIG. 4B, a surface of slab portion 28 is located at the same height as the surface of terrace 27. Slab portion 28 is integral with terrace 27 and extends parallel to the XY plane, and forms a surface of silicon layer 16.

As illustrated in FIG. 1, semiconductor element 30 includes a slab portion 32 (second slab portion), two projecting portions 33, a mesa 35, an electrode 48, and an electrode 49. Projecting portion 33, slab portion 32, and projecting portion 33 are arranged in order from the +X side to the −X side. Mesa 35 extends from one projecting portion 33 to the other projecting portion 33.

As illustrated in FIG. 2A and FIG. 4B, slab portion 32 is bonded to slab portion 28 of substrate 10. Slab portion 32 is plate-shaped and has a width larger than projecting portion 33 and mesa 35. The planar shape of slab portion 32 is rectangular. In the X-axis direction, slab portion 32 does not protrude outward from slab portion 28. Slab portion 28 extends from a position at which slab portion 28 overlaps slab portion 32 to the outside of slab portion 32. As illustrated in FIG. 2A to FIG. 4A, projecting portion 33 extends parallel to the X-axis, projects from slab portion 32 to be located on waveguide 20, and is located on tapered portion 21 of waveguide 20.

Projecting portion 33 has a tapered portion 34 (second tapered portion). In the example of FIG. 2A, entire projecting portion 33 is tapered portion 34. A width of tapered portion 34 increases as a distance from slab portion 32 decreases and decreases as the distance from slab portion 32 increases. Projecting portion 33 has a width larger than that of mesa 35. The widths of projecting portion 33 are set to as W2, W3, W4, and W5 from a tip of projecting portion 33 toward slab portion 32. The width W2 is, for example, 1.7 μm. The width W3 is, for example, 2.7 μm. The width W4 is, for example, 3.7 μm. The width W5 of a portion of projecting portion 33 connected to slab portion 32 is, for example, 5.7 μm.

As illustrated in FIG. 2A, mesa 35 extends parallel to the X-axis from a position at which mesa 35 overlaps waveguide 20 to a position at which mesa 35 overlaps waveguide 22. As illustrated in FIG. 2A and FIG. 3C to FIG. 4C, mesa 35 is located on or above slab portion 32 and projecting portion 33. Mesa 35 has a portion 36 and a portion 37. Portion 36 projects out of slab portion 32 and is located on or above projecting portion 33 and waveguide 20. Portion 37 is located on or above slab portion 32 and waveguide 22.

As illustrated in FIG. 2A, portion 36 of mesa 35 has a tapered portion 38 (third tapered portion). Tapered portion 38 is located on or above projecting portion 33. A width of tapered portion 38 increases as a distance from slab portion 28 decreases and decreases as the distance from slab portion 28 increases. A width W6 at a tip of mesa 35 is, for example, 400 nm.

A tapered portion 31 of semiconductor element 30 projects from slab portion 32 in the X-axis direction, is located on two sides of mesa 35 in the Y-axis direction, and is located between slab portion 32 and tapered portion 38 of mesa 35 in the X-axis direction. A width W7 of a portion of tapered portion 31 connected to slab portion 32 is, for example, 3 μm.

Projecting portion 33 and mesa 35 do not protrude outward from waveguide 20 in a plan view, and are located on an inner side of waveguide 20. Waveguide 20 protrudes from under projecting portion 33 and mesa 35 to the outside of projecting portion 33.

As illustrated in FIG. 3B to FIG. 4C, semiconductor element 30 has a cladding layer 40 (first semiconductor layer), an active layer 42, a cladding layer 44, and a contact layer 46 (the last two layers constitute a second semiconductor layer). As illustrated in FIG. 3B to FIG. 4A, projecting portion 33 of semiconductor element 30 is formed of cladding layer 40.

Mesa 35 includes active layer 42, cladding layer 44, and contact layer 46. As illustrated in FIG. 3C and FIG. 4A, portion 36 of mesa 35 includes active layer 42, cladding layer 44, and contact layer 46, and has a deep ridge structure. As illustrated in FIG. 4B and FIG. 4C, portion 37 of mesa 35 does not include active layer 42, but has cladding layer 44 and contact layer 46, and has a shallow ridge structure.

As illustrated in FIG. 4A, tapered portion 31 is formed of active layer 42. As illustrated in FIG. 4B and FIG. 4C, slab portion 32 includes cladding layer 40 and active layer 42.

Insulating film 11 covers substrate 10, slab portion 32, projecting portion 33, and mesa 35. Insulating film 11 has an opening portion on mesa 35. Electrode 48 is a p-type electrode, is provided in the opening portion, and is in contact with a surface of contact layer 46, and is electrically connected to contact layer 46. Insulating film 11 also has an opening portion at a position separated from mesa 35. Electrode 49 illustrated in FIG. 1 is an n-type electrode and is connected to cladding layer 40 through the opening portion.

Cladding layer 40 is formed of, for example, n-type indium phosphide (n-InP). Active layer 42 has a multiple quantum well (MQW) and includes a barrier layer and a well layer. The plurality of barrier layers and the plurality of well layers are alternately stacked. The barrier layer and the well layer are formed of, for example, i-type gallium indium arsenide phosphide (GaInAsP). Cladding layer 44 is formed of, for example, p-type indium phosphide (p-InP). Contact layer 46 is formed of, for example, p-type gallium indium arsenide (p-GaInAs). The semiconductor layer of semiconductor element 30 may be formed of a III-V group compound semiconductor other than the above.

Electrode 48 and electrode 49 are formed of a metal. Electrode 48 is formed of a stacked body in which titanium (Ti), platinum (Pt), and gold (Au) are stacked so as to be located closer to mesa 35, for example. Electrode 49 is formed of, for example, an alloy of gold, germanium, and nickel (AuGeNi).

Transition structure 102 has the same structure as transition structure 101. Waveguide 22, recess 26, and terrace 27 extend from transition structure 101 to transition structure 102. Recess 26 is located between waveguide 22 and terrace 27. Slab portion 32 of semiconductor element 30 extends from transition structure 101 to transition structure 102 and is located on or above recess 26, terrace 27 and waveguide 22. Recess 26 is sealed by slab portion 28 and slab portion 32.

A voltage is applied to semiconductor element 30 by using electrode 48 and electrode 49, and carriers are injected into active layer 42. Active layer 42 has an optical gain and generates light by carrier injection. The wavelength of the light is, for example, 1.55 μm. Semiconductor element 30 and substrate 10 are optically coupled by evanescent optical coupling. The light generated in semiconductor element 30 propagates through waveguide 22 and is transferred to waveguides 20 in transition structure 101 and transition structure 102. The light resonates in ring resonator 103 and is reflected by loop mirror 104. The reflected light propagates toward semiconductor element 30 and is transferred from waveguide 20 to waveguide 22 in transition structure 101 and transition structure 102. The light is repeatedly reflected, and thus laser oscillation occurs.

The diameter of one of two ring resonators 103 is different from the diameter of the other. The oscillation wavelength is determined by the vernier effect of two ring resonators 103. The transmittance of one of two loop mirrors 104 is higher than the transmittance of the other. A part of the laser light is transmitted through loop mirror 104 and emitted to the outside of semiconductor optical device 100.

In FIG. 3A to FIG. 4C, the shape of the light is schematically illustrated by an ellipse with a dashed line. The mode of the light is defined by the waveguide 20 and mesa 35. In the cross-section of FIG. 3A, light is intensively distributed in waveguide 20. In transition structure 101, light is transferred from waveguide 20 to semiconductor element 30. Since each of projecting portion 33 and mesa 35 of semiconductor element 30 has a taper shape, the light gradually transfers, and the mode of the light is slowly converted. Light is confined around mesa 35 of semiconductor element 30 and is less likely to spread. Thus, the mode of the light is maintained. It is possible to reduce the loss of light.

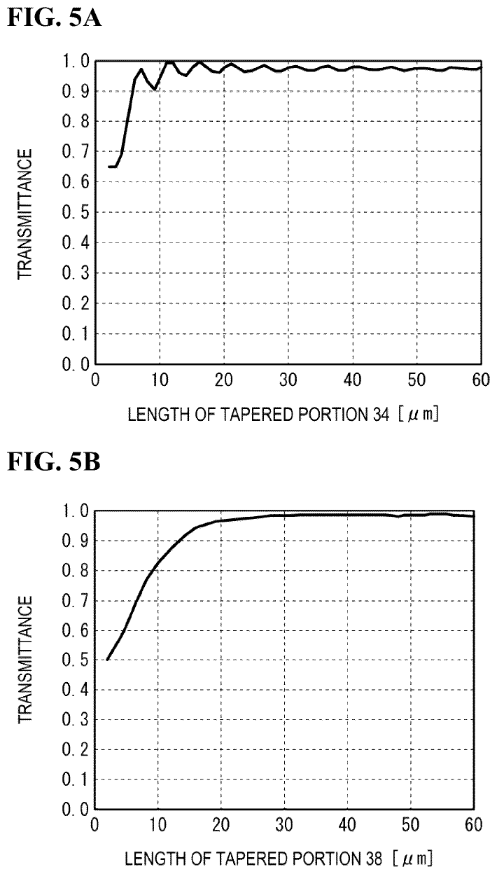

FIG. 5A and FIG. 5B are diagrams illustrating the calculation result of the transmittance. FIG. 5A illustrates the calculation result of the transmittance in projecting portion 33. The horizontal axis represents the length of tapered portion 34 of projecting portion 33. The vertical axis represents the transmittance of light. When tapered portion 34 is 5 μm or more, the transmittance exceeds 0.9.

FIG. 5B illustrates the calculation result of the transmittance in tapered portion 38 of mesa 35. The horizontal axis represents the length of tapered portion 38. The vertical axis represents the transmittance of light. The transmittance of tapered portion 38 increases as a length of tapered portion 38 increase, and thus the transmittance exceeds 0.9 at 15 μm or more. As described above, tapered projecting portion 33 and mesa 35 can reduce the loss of light.

### Manufacturing Method

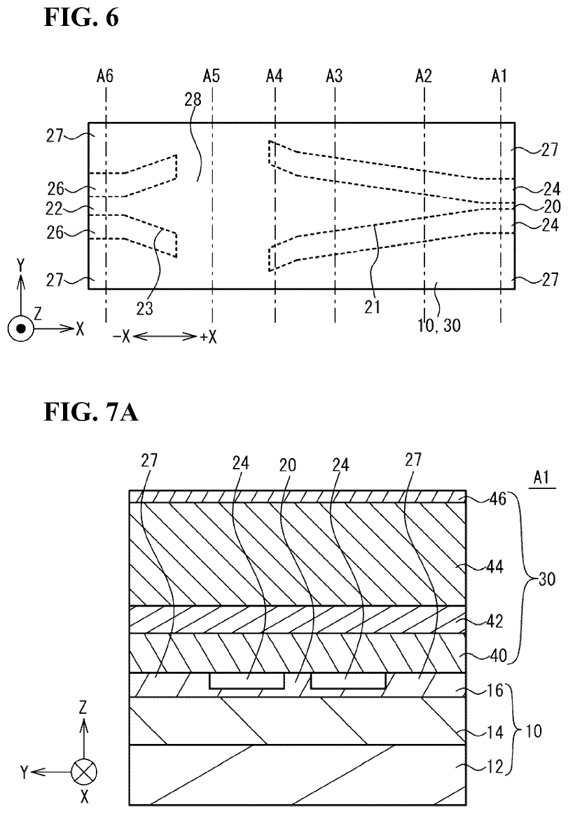

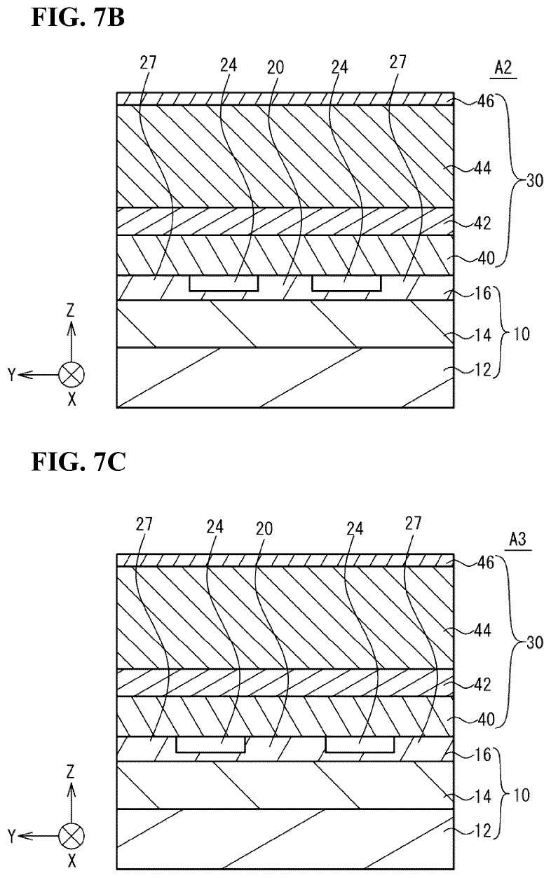

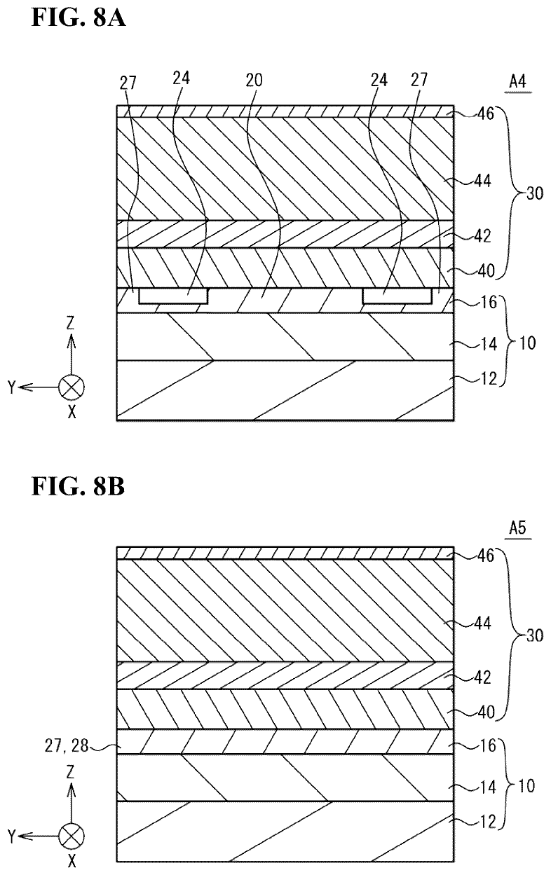

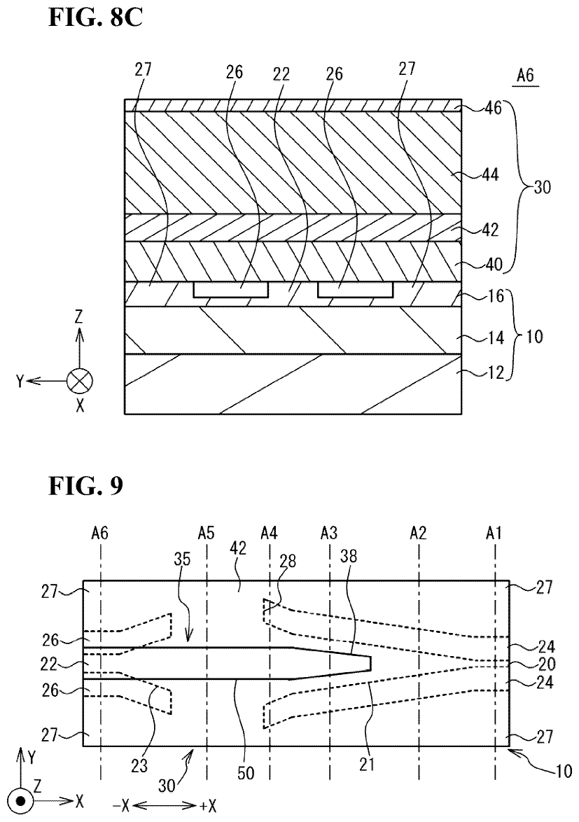

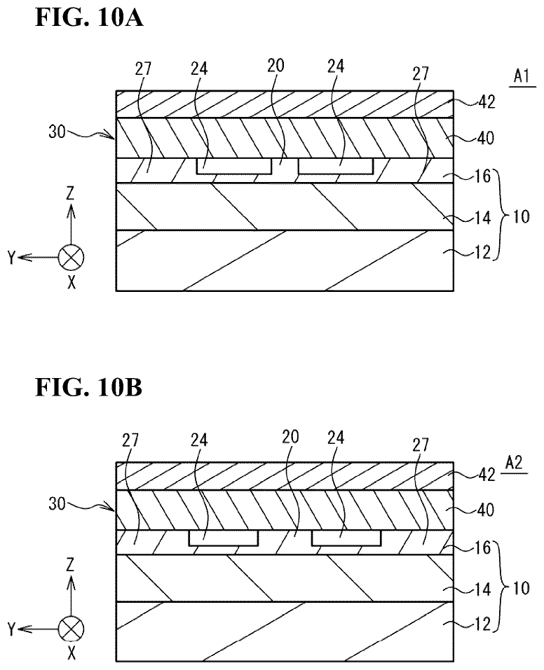

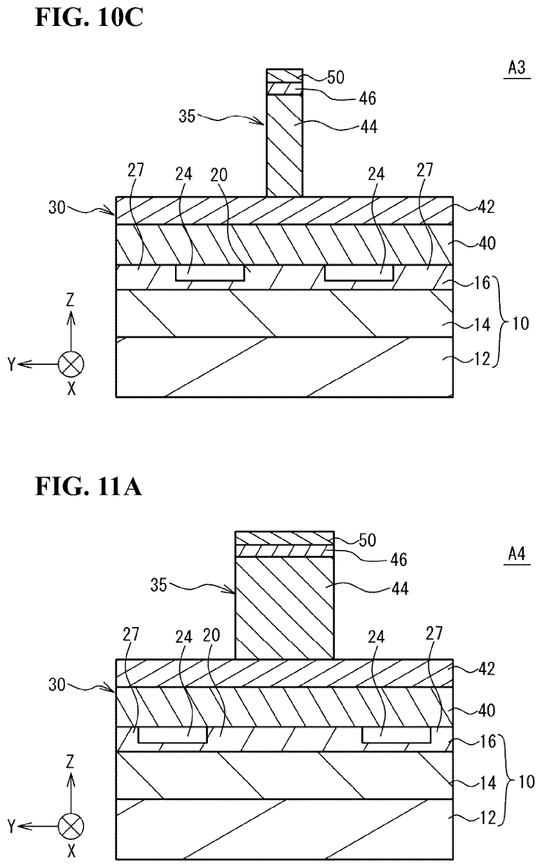

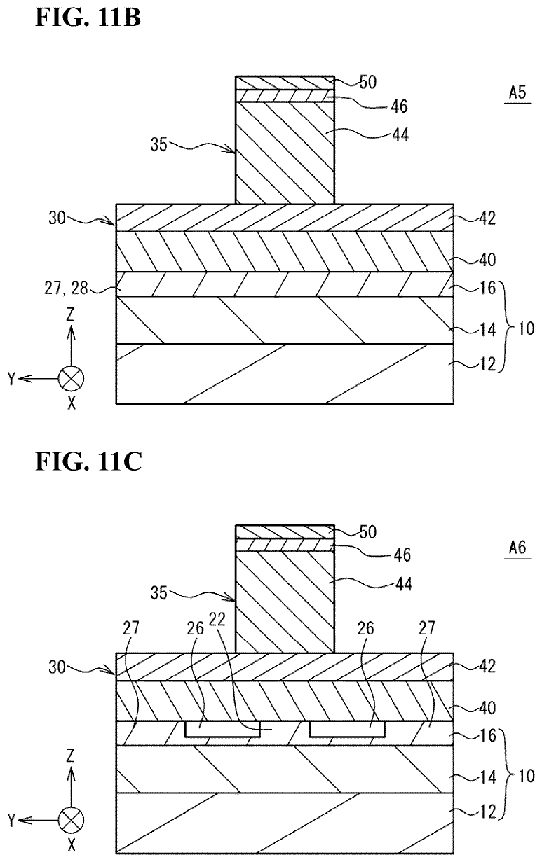

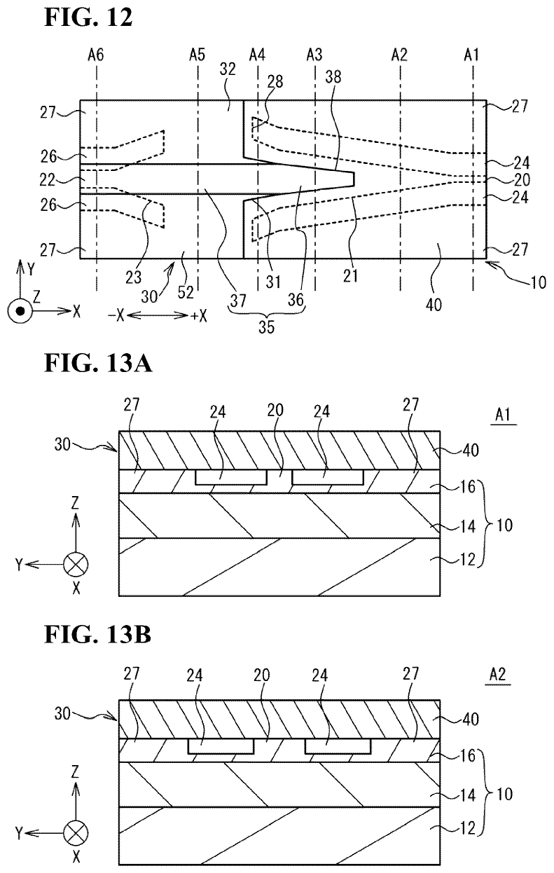

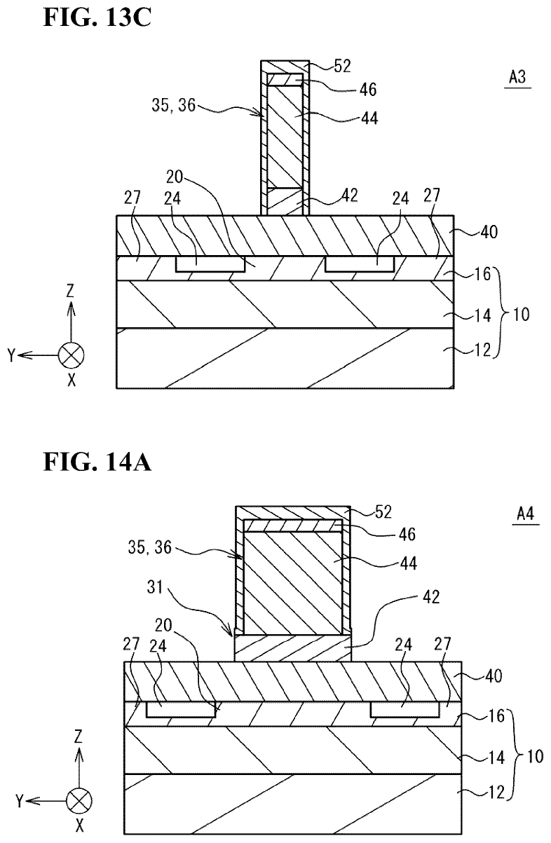

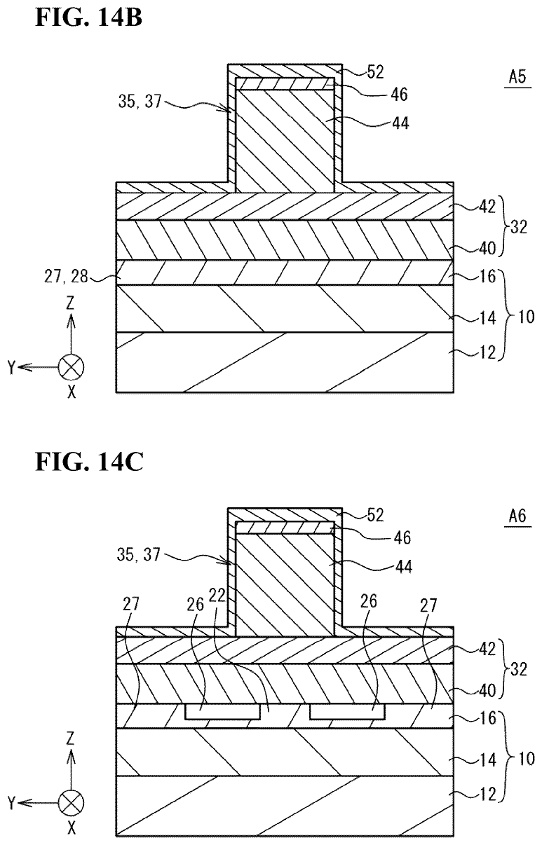

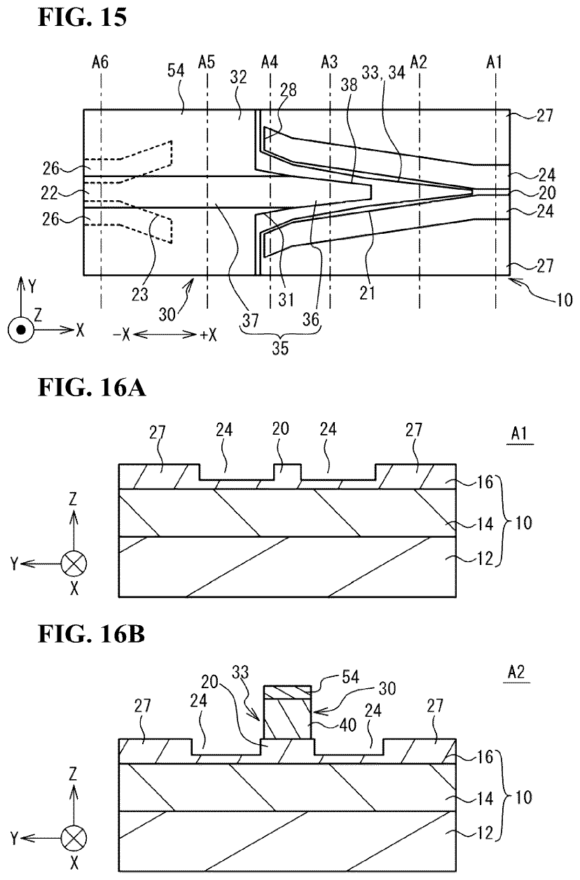

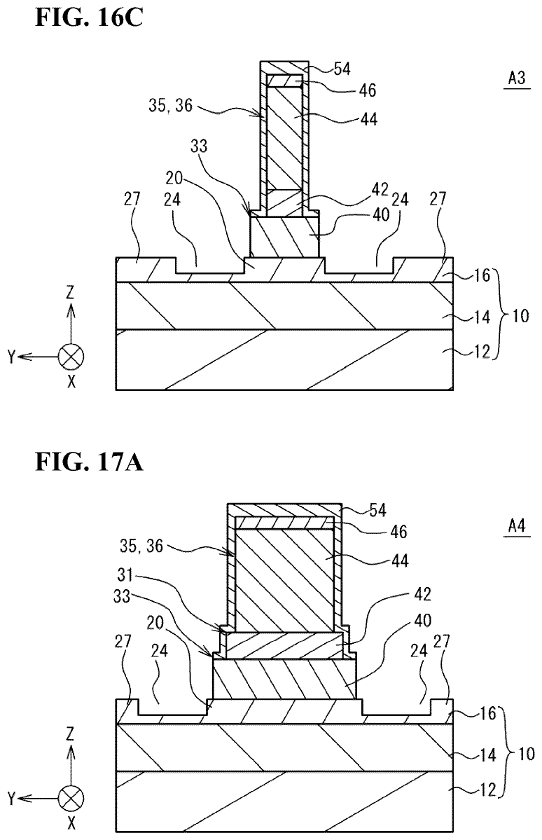

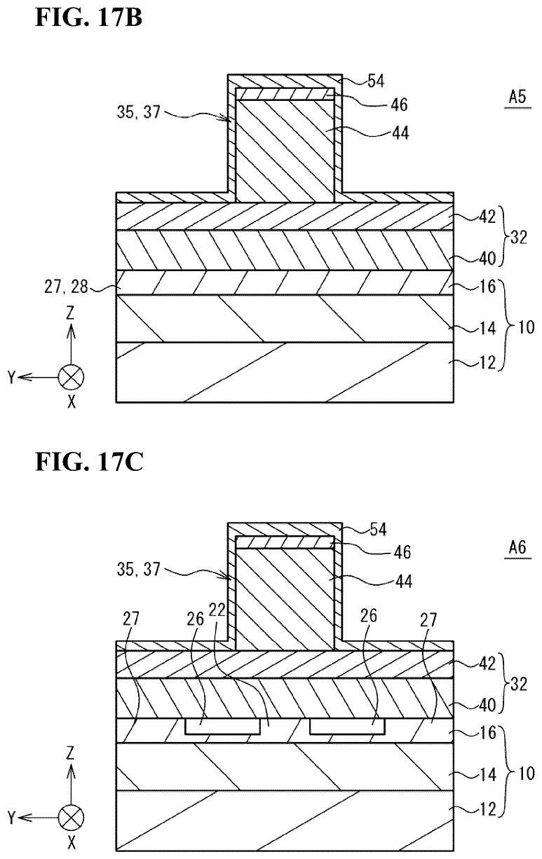

FIG. 6, FIG. 9, FIG. 12 and FIG. 15 are plan views illustrating a method of manufacturing of semiconductor optical device 100. FIG. 7A to FIG. 8C are cross-sectional views illustrating a method of manufacturing of semiconductor optical device 100, in which cross-sections taken along lines A1 to A6 of FIG. 6 are illustrated, respectively. FIG. 10A to FIG. 11C are cross-sectional views illustrating a method of manufacturing of semiconductor optical device 100, in which cross-sections taken along lines A1 to A6 of FIG. 9 are illustrated. FIG. 13A to FIG. 14C are cross-sectional views illustrating a method of manufacturing of semiconductor optical device 100, in which cross-sections taken along lines A1 to A6 of FIG. 12 are illustrated. FIG. 16A to FIG. 17C are cross-sectional views illustrating a method of manufacturing of semiconductor optical device 100, in which cross-sections taken along lines A1 to A6 of FIG. 15 are illustrated.

In a step prior to FIG. 6, for example, dry-etching is performed on silicon layer 16 of substrate 10. A portion exposed from a mask (not illustrated) is etched to form recess 24 and recess 26. A portion covered with the mask (not illustrated) is not etched. Waveguide 20 and waveguide 22, terrace 27, and slab portion 28 are formed.

On an InP substrate different from the SOI substrate (substrate 10), contact layer 46, cladding layer 44, active layer 42, and cladding layer 40 are epitaxially grown in order by metal organic chemical vapor deposition (MOCVD) or the like. The InP substrate is diced to form semiconductor element 30. Semiconductor element 30 immediately after dicing is a rectangular parallelepiped, and does not have slab portion 32, projecting portion 33, and mesa 35.

As illustrated in FIG. 6 to FIG. 8C, semiconductor element 30 is bonded to the top surface of substrate 10. One surface of silicon layer 16 and one surface of semiconductor element 30 are irradiated with plasma to activate these surfaces. The surface of semiconductor element 30 is brought into contact with the surface of silicon layer 16, and semiconductor element 30 is bonded to silicon layer 16. Semiconductor element 30 covers, for example, a top surface of silicon layer 16, and is located on or above waveguide 20, waveguide 22, recess 24, recess 26, terrace 27, and slab portion 28. After the bonding, the InP substrate is removed by wet-etching. The semiconductor layers from contact layer 46 to cladding layer 40 remain.

As illustrated in FIG. 9 to FIG. 11C, a portion of semiconductor element 30 is covered with a mask 50. For example, dry-etching and wet-etching are performed on semiconductor element 30 to form mesa 35. For example, a hydrochloric acid-based chemical solution is used as an etchant for the wet-etching. A portion of semiconductor element 30 covered with mask 50 is not etched and becomes mesa 35. Mesa 35 is formed of cladding layer 44 and contact layer 46. In a portion exposed from mask 50, contact layer 46 and cladding layer 44 are etched, and active layer 42 is exposed. Cladding layer 40 and active layer 42 cover waveguide 20, waveguide 22, recess 24, recess 26, terrace 27, and slab portion 28 of silicon layer 16. After the etching, mask 50 is removed.

As illustrated in FIG. 12 to FIG. 14C, a mask 52 is provided on semiconductor element 30. As illustrated in FIG. 13C to FIG. 14C, mask 52 covers a top and side surfaces of mesa 35 and a portion of active layer 42. The other portion of active layer 42 is exposed from mask 52. For example, wet-etching is performed to remove a portion of active layer 42 exposed from mask 52. As illustrated in FIG. 13A to FIG. 13C, cladding layer 40 is exposed in the wet-etched portion. The portion covered with mask 52 is not etched, and mesa 35, active layer 42, and cladding layer 40 remain.

As illustrated in FIG. 13C and FIG. 14A, portion 36 of mesa 35 includes active layer 42 and is a deep ridge structure. As illustrated in FIG. 14A, a portion of cladding layer 40 that protrudes in the Y-axis direction from mesa 35 serves as tapered portion 31. As illustrated in FIG. 14B and FIG. 14C, portion 37 of mesa 35 includes cladding layer 44 and contact layer 46, and is a shallow ridge structure. Active layer 42 and cladding layer 40 form slab portion 32. After the etching, mask 52 is removed.

As illustrated in FIG. 15 to FIG. 17C, a mask 54 is provided on semiconductor element 30. As illustrated in FIG. 16C to FIG. 17C, mask 54 covers the top and side surfaces of mesa 35. As illustrated in FIG. 17B and FIG. 17C, mask 54 covers slab portion 32. As illustrated in FIG. 16B, mask 54 covers a portion of cladding layer 40 above waveguide 20. A portion of cladding layer 40 is exposed from mask 54. For example, wet-etching is performed to remove a portion of cladding layer 40 exposed from mask 54, and thus projecting portion 33 is formed. Cladding layer 40 is removed by wet-etching, so that silicon layer 16 is exposed. After the etching, mask 54 is removed.

Insulating film 11 is formed by a plasma enhanced chemical vapor deposition method (PECVD) or the like as illustrated in FIG. 3A to FIG. 4C. An opening portion of insulating film 11 is formed on mesa 35. Electrode 48 and electrode 49 are formed in the opening portions by vacuum deposition or the like. Semiconductor optical device 100 is formed by the above steps.

As described above, semiconductor element 30 is wet-etched after the bonding. In the wet-etching step, insulating film 11 is not formed, and recess 24 is exposed. In the wet-etching step, the etchant enters recess 24. Since slab portion 28 is provided between recess 24 and recess 26, the etchant is blocked by slab portion 28, and the etchant is kept from entering into recess 26. Thus, semiconductor element 30 is kept from being etched from the bonding interface.

### Comparative Example

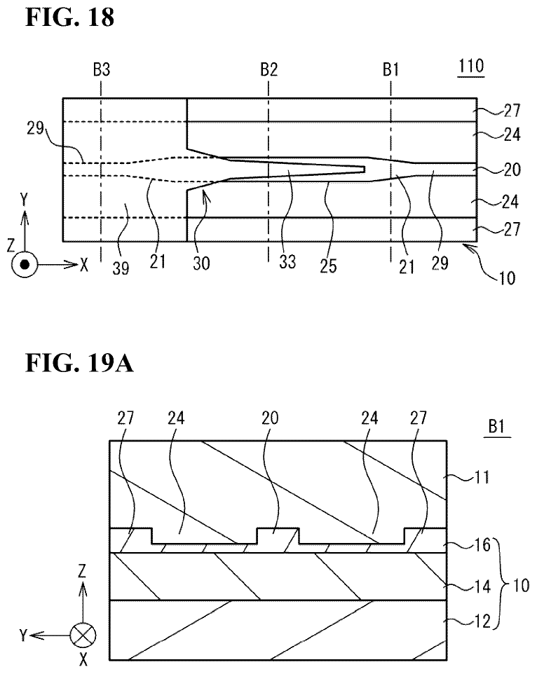

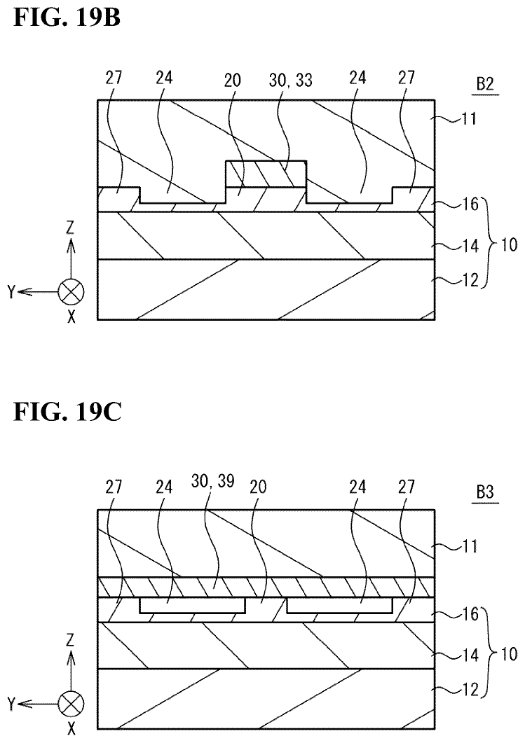

FIG. 18 is a plan view illustrating a semiconductor optical device 110 according to a comparative example. FIG. 19A to FIG. 19C are cross-sectional views illustrating semiconductor optical device 110, in which cross-sections taken along a line B1, a line B2, and a line B3 of FIG. 18, respectively. The description of the same configuration as that of the embodiment will be omitted.

As illustrated in FIG. 18 to FIG. 19C, substrate 10 has waveguide 20, recess 24, and terrace 27, but does not have the slab portion. Waveguide 20, recess 24, and terrace 27 extend from one end to the other end of substrate 10 in the X-axis direction. Waveguide 20 has tapered portion 21, a portion 29, and a portion 25. In the X-axis direction, portion 29, tapered portion 21, portion 25, tapered portion 21, and portion 29 are arranged in this order. Portion 25 is wider than portion 29. Tapered portion 21 is connected to portion 29 and portion 25.

Semiconductor element 30 includes a slab portion 39 and projecting portion 33. Projecting portion 33 projects from slab portion 39 in the X-axis direction and is located on portion 25 of waveguide 20. Slab portion 39 is located on or above waveguide 20, recess 24 and terrace 27.

Recess 24 is located on each of two sides of waveguide 20 and extends from the outside of semiconductor element 30 to under semiconductor element 30. In the step of performing wet-etching on semiconductor element 30, a liquid such as an etchant enters into recess 24 and flows to under semiconductor element 30. Semiconductor element 30 is etched from the lower surface (bonding interface), and thus semiconductor element 30 is damaged. The bonding strength of semiconductor element 30 to substrate 10 is reduced.

According to the present embodiment, silicon layer 16 of substrate 10 has waveguide 20, waveguide 22, recess 24, recess 26, and slab portion 28. Slab portion 28 is located between recess 24 and recess 26 to block between recess 24 and recess 26. Recess 24 is terminated before semiconductor element 30 and is not connected to recess 26. Semiconductor element 30 is bonded to silicon layer 16 and has slab portion 32. Slab portion 32 is located on or above slab portion 28, waveguide 22, recess 26, and terrace 27. Recess 26 is sealed by slab portion 28 and slab portion 32. A liquid such as an etchant is less likely to enter into recess 26. Unintended etching of semiconductor element 30 can be reduced.

Semiconductor element 30 is formed of a III-V group compound semiconductor. After the bonding, wet-etching is performed to form slab portion 32, projecting portion 33, mesa 35, and the like. Semiconductor element 30 includes a cladding layer of InP, active layer 42 of InGaAsP, and contact layer 46 of InGaAs. In the wet-etching, an etchant suitable for these semiconductors is used. For example, a hydrochloric acid-based solution is used as the etchant. Since the etchant is kept from entering into recess 26 by slab portion 28 and slab portion 32, unintended etching of semiconductor element 30 can be reduced.

Substrate 10 and semiconductor element 30 form transition structure 101 and transition structure 102. As illustrated in FIG. 2A, semiconductor element 30 has projecting portion 33 and mesa 35. Projecting portion 33 is located on or above waveguide 20. Mesa 35 is located on projecting portion 33 and slab portion 32. In the transition structure, light is transferred between substrate 10 and semiconductor element 30. Light propagates through the waveguide and is confined around mesa 35. It is possible to reduce the loss of light.

Semiconductor element 30 has cladding layer 40, active layer 42, cladding layer 44, and contact layer 46. Slab portion 32 includes cladding layer 40 and active layer 42. Projecting portion 33 includes cladding layer 40. Portion 36 of mesa 35 is located on projecting portion 33 and includes active layer 42, cladding layer 44, and contact layer 46. The coupling efficiency between semiconductor element 30 and substrate 10 can be increased, and the light can be gradually transferred. Portion 37 of mesa 35 is located on slab portion 32 and includes cladding layer 44 and contact layer 46. The light is confined around mesa 35. It is possible to reduce the loss of light.

Cladding layer 40 is formed of n-type InP. Cladding layer 44 is formed of p-type InP. Contact layer 46 is formed of p-type InGaAs. Active layer 42 is formed of undoped GaInAsP. A p-i-n bond is formed in semiconductor element 30. Carriers are injected into active layer 42, and light can be generated. Light is concentrated around mesa 35 of semiconductor element 30, and loss can be reduced.

As illustrated in FIG. 2A, waveguide 20 protrudes outward of projecting portion 33 and mesa 35. Projecting portion 33 and mesa 35 do not protrude, and are located on the inner side of waveguide 20. Etching of semiconductor element 30 from the bonding interface can be reduced. Mesa 35 is located on the inner side of projecting portion 33. Projecting portion 33 and mesa 35 are easy to manufacture by etching. After mesa 35 is formed, it is only necessary that projecting portion 33 is formed under mesa 35.

Waveguide 20 has tapered portion 21. Projecting portion 33 has tapered portion 34. Mesa 35 has tapered portion 38. It is possible to reduce the loss of light by enhancing coupling efficiency between semiconductor element 30 and substrate 10.

Tapered portion 34 of projecting portion 33 is bonded to tapered portion 21 of waveguide 20. Tapered portion 38 of mesa 35 is located on or above tapered portion 34 of projecting portion 33. The coupling efficiency between semiconductor element 30 and substrate 10 can be increased by the multi-step tapered structure.

Insulating film 11 covers silicon layer 16 and semiconductor element 30 of substrate 10. Since insulating film 11 functions as a cladding layer, it is possible to reduce the loss of light.

Semiconductor optical device 100 of FIG. 1 is a wavelength tunable laser diode. Semiconductor optical device 100 may be an optical device other than the wavelength tunable laser diode.

### Modification

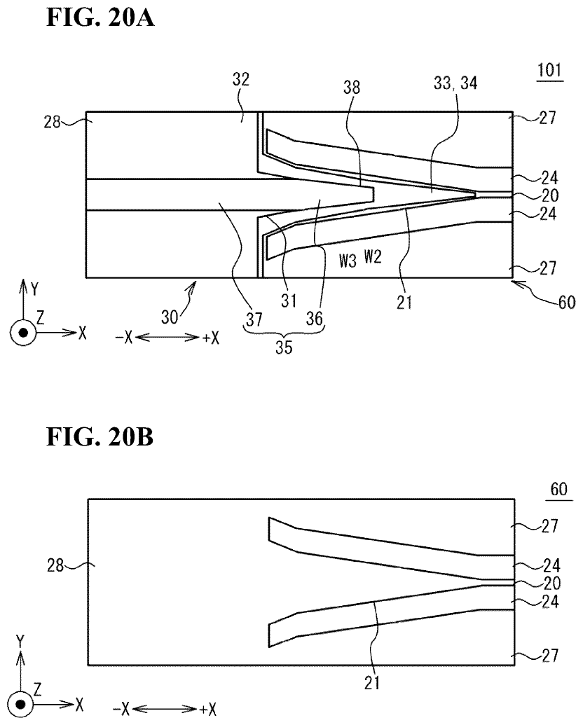

FIG. 20A is a plan view illustrating a semiconductor optical device according to a modification, in which one transition structure 101 is illustrated as in FIG. 2A. FIG. 20B is a plan view illustrating a substrate 60. The description of the same configuration as that of the embodiment will be omitted. As illustrated in FIG. 20A and FIG. 20B, substrate 60 has waveguide 20, recess 24, terrace 27, and slab portion 28. Waveguide 20 is connected to one end of slab portion 28. Slab portion 28 extends from one transition structure 101 to the other transition structure 102. In the X-axis direction, the waveguide and the recess are not provided between transition structure 101 and transition structure 102. Slab portion 32 of semiconductor element 30 is bonded to slab portion 28.

According to the modification, since slab portion 28 is provided, recess 24 is terminated in the vicinity of the end of semiconductor element 30. A liquid such as an etchant is less likely to enter under semiconductor element 30. Unintended etching of semiconductor element 30 can be reduced.

Although the embodiment of the present disclosure have been described in detail, the present disclosure is not limited to the specific embodiment, and various modifications and changes can be made within the scope of the gist of the present disclosure described in the claims.

What is claimed is:

1. A semiconductor optical device comprising:
a substrate having a silicon layer; and
a semiconductor element formed of a III-V group compound semiconductor and bonded to the silicon layer,
wherein the silicon layer includes a first waveguide, a first recess, a terrace, and a first slab portion,
wherein the first recess is a recessed portion lower than a surface of the first waveguide, a surface of the terrace, and a surface of the first slab portion,
wherein the first recess and the terrace are disposed in this order on each of two sides of the first waveguide,
wherein the first waveguide is connected to one end of the first slab portion,
wherein the first slab portion is connected to the terrace,
wherein the semiconductor element includes a second slab portion, a projecting portion, and a mesa,
wherein the second slab portion is located on or above the first slab portion,
wherein the projecting portion projects from the second slab portion to be located on or above the first waveguide, and
wherein the mesa is located on or above the second slab portion and the projecting portion.

2. The semiconductor optical device according to claim 1,
wherein the silicon layer includes a second waveguide and a second recess,
wherein the second waveguide is connected to an end of the first slab portion, the end being opposite to the first waveguide,
wherein the second recess and the terrace are disposed in this order on each of two sides of the second waveguide,
wherein the first slab portion is located between the first recess and the second recess,
wherein the second slab portion is located on or above the first slab portion, the second waveguide, the second recess, and the terrace that is disposed on each of two sides of the second waveguide, and
wherein the mesa extends from a position at which the mesa overlaps the first waveguide to a position at which the mesa overlaps the second waveguide.

3. The semiconductor optical device according to claim 1,
wherein the semiconductor element has a first semiconductor layer, an active layer, and a second semiconductor layer,
wherein the first semiconductor layer, the active layer, and the second semiconductor layer are stacked so as to be located closer to the substrate in this order,
wherein the projecting portion includes the first semiconductor layer,
wherein the second slab portion includes the first semiconductor layer and the active layer,
wherein a portion of the mesa located on or above the projecting portion includes the active layer and the second semiconductor layer, and
wherein a portion of the mesa located on or above the second slab portion includes the second semiconductor layer.

4. The semiconductor optical device according to claim 3,
wherein the first semiconductor layer and the second semiconductor layer each contain indium phosphide, and
wherein the active layer contains gallium indium arsenide phosphide.

5. The semiconductor optical device according to claim 3,
wherein the first semiconductor layer is an n-type semiconductor layer, and
wherein the second semiconductor layer is a p-type semiconductor layer.

6. The semiconductor optical device according to claim 1,
wherein the projecting portion is located on an inner side of the first waveguide, and
wherein the mesa is located on an inner side of the projecting portion.

7. The semiconductor optical device according to claim 1,
wherein the first waveguide includes a first tapered portion,
wherein the projecting portion includes a second tapered portion,
wherein the mesa includes a third tapered portion, and
wherein a width of the first tapered portion, a width of the second tapered portion, and a width of the third tapered portion each increase as a distance from the first slab portion decreases and each decrease as the distance from the first slab portion increases.

8. The semiconductor optical device according to claim 7,
wherein the second tapered portion is bonded to the first tapered portion, and
wherein the third tapered portion is located on or above the second tapered portion.

9. The semiconductor optical device according to claim 1, comprising an insulating film covering the silicon layer and the semiconductor element.

10. A method of manufacturing a semiconductor optical device, the method comprising:
bonding a semiconductor element to a silicon layer of a substrate, the semiconductor element being formed of a III-V group compound semiconductor; and
wet-etching the semiconductor element that has been bonded,
wherein the silicon layer includes a first waveguide, a first recess, a terrace, and a first slab portion,
wherein the first recess is a recessed portion lower than a surface of the first waveguide, a surface of the terrace, and a surface of the first slab portion,
wherein the first recess and the terrace are disposed in this order on each of two sides of the first waveguide,
wherein the first waveguide is connected to one end of the first slab portion,
wherein the first slab portion is connected to the terrace,
wherein the bonding the semiconductor element is bonding the semiconductor element to the first waveguide, the first slab portion, and the terrace that is disposed on each of the two sides of the first waveguide,
wherein, in the wet-etching, a second slab portion, a projecting portion, and a mesa are formed at the semiconductor element,
wherein the second slab portion is located on or above the first slab portion,
wherein the projecting portion projects from the second slab portion to be located on or above the first waveguide, and
wherein the mesa is located on or above the second slab portion and the projecting portion.

11. The method of manufacturing a semiconductor optical device according to claim 10,
wherein the silicon layer includes a second waveguide and a second recess,
wherein the second waveguide is connected to an end of the first slab portion, the end being opposite to the first waveguide,
wherein the second recess and the terrace are disposed in this order on each of two sides of the second waveguide,
wherein the first slab portion is located between the first recess and the second recess,
wherein the bonding is bonding the semiconductor element to the first waveguide, the first slab portion, the second waveguide, and the terrace that is disposed on each of the two sides of the first waveguide and on each of the two sides of the second waveguide, and
wherein the mesa extends from a position at which the mesa overlaps the first waveguide to a position at which the mesa overlaps the second waveguide.
